(19) United States
(12) Patent Application Publication
(10) Pub. No.: US 2013/0062736 A1
(43) Pub. Date: Mar. 14, 2013

(54) POST-POLYMER REVEALING OF THROUGH-SUBSTRATE VIA TIPS

(71) Applicants: JEFFREY E. BRIGHTON, FRISCO, TX (US); JEFFREY A. WEST, DALLAS, TX (US); RAJESH TIWARI, PLANO, TX (US)

(72) Inventors: JEFFREY E. BRIGHTON, FRISCO, TX (US); JEFFREY A. WEST, DALLAS, TX (US); RAJESH TIWARI, PLANO, TX (US)

(73) Assignee: TEXAS INSTRUMENTS INCORPORATED, Dallas, TX (US)

(21) Appl. No.: 13/228,594

(22) Filed: Sep. 9, 2011

(51) Int. Cl. H01L 29/45; H01L 21/28

(52) U.S. Cl. 257/621; 438/653; 257/E21.191; 257/E29.143

(57) ABSTRACT

A method of forming semiconductor die includes forming a layer of polymer or a precursor of the polymer on a bottomside of a substrate having a topside including active circuitry and a bottomside, and a plurality of through-substrate-vias (TSVs). The TSVs have a liner including at least a dielectric liner and an inner metal core that extends to TSV tips that protrude from the bottomside. The layer of polymer or precursor and liner cover the plurality of TSV tips, and the layer of polymer or precursor is between the TSV tips on the bottomside. The polymer or precursor and the liner are removed from over a top of the TSV tips to reveal the inner metal core.

### FIELD

Disclosed embodiments relate to electronic devices, and more particularly to semiconductor die having through-substrate vias including protruding through-substrate via tips.

### BACKGROUND

As known in the art, through-substrate vias (referred to herein as TSVs), which are commonly referred to as through-silicon vias in the case of silicon substrates, are vertical electrical connections that extend the full thickness of the semiconductor die from one of the electrically conductive levels formed on the topside surface of the semiconductor die (e.g., contact level or one of the back end of the line (BEOL) metal interconnect levels) to its bottomside surface. Such semiconductor die are referred to herein as “TSV die.”

The vertical electrical paths are significantly shortened in length relative to conventional wire bonding technology, generally leading to significantly faster device operation. In one arrangement, the TSVs terminate on the bottomside of the TSV die as protruding TSV tips, such as protruding a distance of 5 μm to 15 μm from the bottomside substrate (e.g., silicon) surface. To form the protruding tips, the TSV die are commonly thinned while in wafer form while bonded to a carrier wafer to expose the TSVs and to form the tips, such as to a die thickness of 25 μm to 100 μm, using a process generally including backgrinding. The TSV die can be bonded face-up or face-down, and can be bonded to from both of its sides to enable formation of stacked die devices.

Processing to form TSV die having protruding TSV tips includes revealing the core metal of the TSV tips to allow bonding thereto. During certain TSV tip reveal integration schemes, the bottomside of the substrate (e.g., a silicon wafer) and TSV core metal are simultaneously exposed, such as by Chemical Mechanical Polishing/Planarization (CMP) or grinding, which can lead to core metal contamination on the bottomside of the wafer. Device leakage can result if a core metal such as copper diffuses into junction areas on the topside of the die, such as during thermo-compression (TC) bonding.

### SUMMARY

Disclosed embodiments include methods of forming semiconductor wafers that have a plurality of through substrate vias (TSV) die (“TSV die”) which include TSV tips that protrude from a bottomside of the die. Such methods reveal the core metal (e.g., Cu) on the top of the TSV tips after a layer of polymer or polymer precursor is formed on the bottomside of the substrate (e.g., a wafer). Hereafter in this specification the term “polymer” will refer to both polymer and polymer precursor.

Disclosed embodiments recognize having the layer of polymer or polymer precursor on the substrate (e.g., silicon) surface during the reveal step prevents core metal removed from the TSV tip during revealing from directly contacting the substrate surface, and the layer of polymer effectively blocks core metal ion (e.g., Cu ion) diffusion into the substrate. Accordingly, even though the assembly processing may include significant heating (e.g., TC bonding, such as around 250° C. to 280° C. for a brief period), core metal such as copper is prevented from diffusing into junction areas on the topside of the die which otherwise can result in increased junction leakage.

Disclosed embodiments include forming a layer of polymer on the bottomside of the semiconductor die to coat over the protruding TSV tips, such as using a spin-on or lamination process. A wet strip or CMP is then performed to remove polymer from the TSV tips. CMP is used to remove the TSV liner comprising a dielectric liner and an optional diffusion barrier layer from over the top of the TSV tips to reveal the core metal.

### BRIEF DESCRIPTION OF THE DRAWINGS

FIG. 1 is a flow chart showing steps in an example method of forming TSV die having a plurality of TSVs, according to a disclosed embodiment.

FIGS. 2A-E show successive cross sectional depictions corresponding to steps in an example method of fabricating TSV die, according to an example embodiment.

FIGS. 3A and B show successive cross sectional depictions corresponding to steps in another example method of fabricating TSV die, according to an example embodiment.

FIG. 4 is a simplified cross sectional depiction of an example TSV die having protruding TSV tips from bottomside of the substrate and a layer of polymer between the TSV tips, wherein the polymer is substantially flush with respect to the inner metal core top of the TSV tips, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

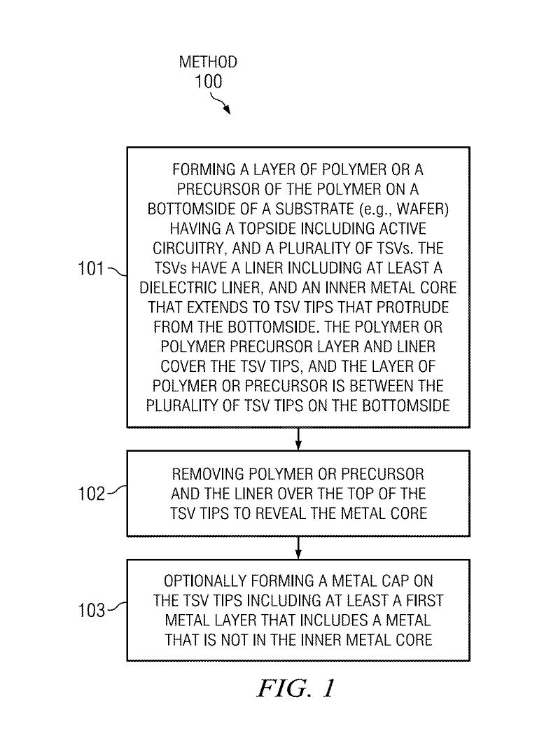

FIG. 1 is a flow chart showing steps in an example method 100 of forming TSV die having a plurality of TSVs, such as through silicon vias in the case of a silicon substrate, according to a disclosed embodiment. Step 101 comprises forming a layer of polymer on a bottomside of a substrate (e.g., wafer) having a topside including active circuitry, and a plurality of TSVs. The polymer can comprise a variety of relatively high temperature tolerant (e.g., tolerant to at least 250° C. for a brief period) polymers such as benzocyclobutene (BCB), polybenzoxazole (PBO), parylene, or a polyimide (PI). The forming step can comprise a spin-on process. Lamination may generally also be used. Some polymers may also be deposited by chemical vapor deposition (CVD), such as poly(p-xylylene) polymers (parylene).

The TSVs have a liner comprising at least a dielectric liner, and an inner metal core that extends to TSV tips that protrude out from the bottomside. The layer of polymer and the liner cover the TSV tips, and the layer of polymer is also in the field region between the plurality of TSV tips on the bottomside. Step 102 comprises removing the polymer and the liner over the top of the TSV tips to reveal the metal core. In one embodiment the inner metal core comprises copper, and the liner comprises a dielectric liner such as silicon oxide and a diffusion barrier layer such as TaN.

The removing can comprise CMP applied to the bottomside of the substrate. In the case of a curable polymer, curing can take place before or after CMP processing. Although not generally described herein, an optional clean to remove metal originating from the inner metal core of the TSV tips can be done in-situ with the CMP process, or can be a stand-alone post-CMP process.

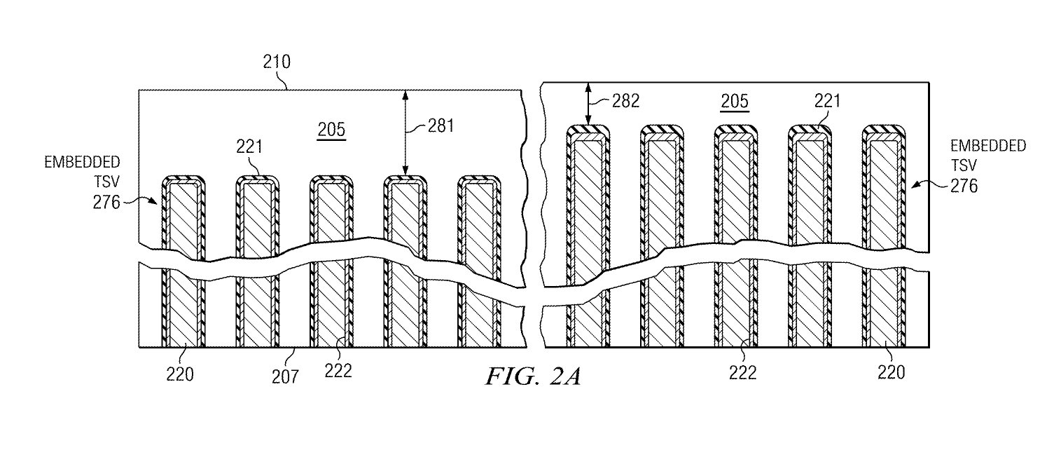

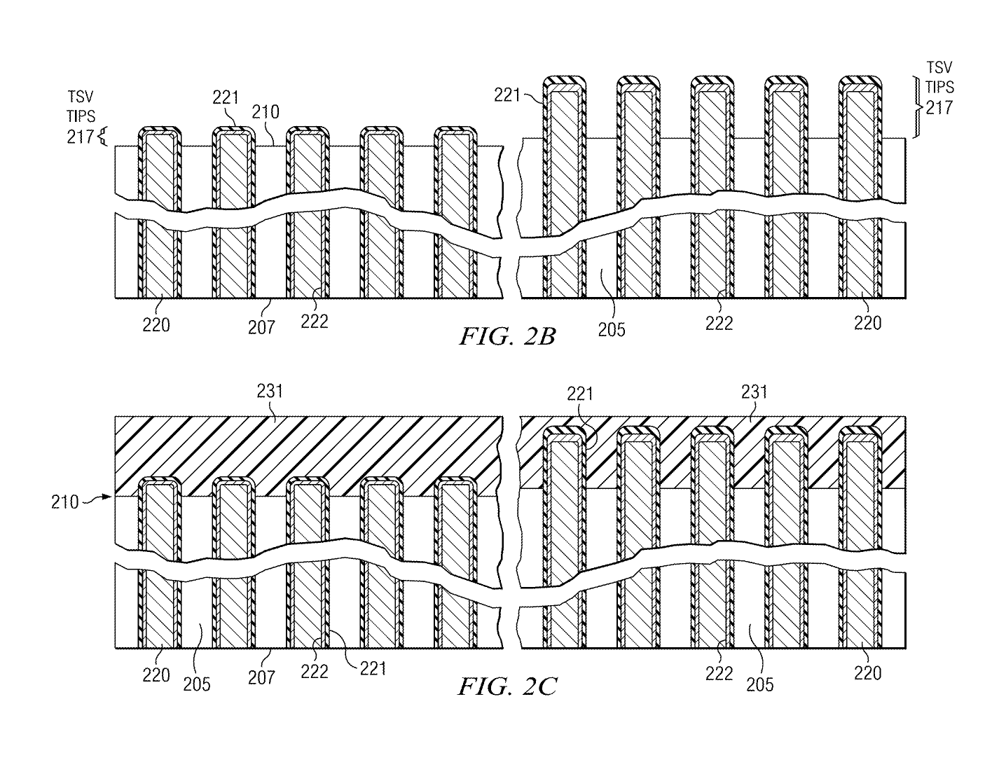

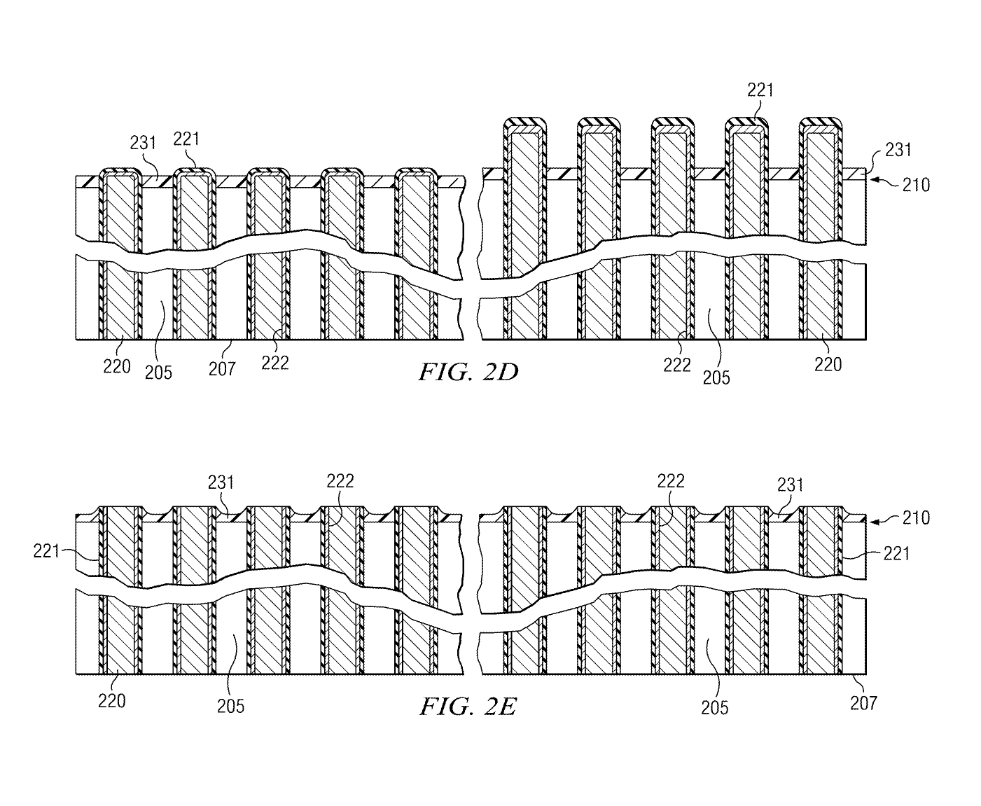

In a first embodiment (see FIGS. 2A-E described below) the removing comprises a CMP process including a CMP slurry that provides a faster removal rate for the dielectric liner and inner metal core as compared to a removal rate for the polymer. In this embodiment a wet strip process removes the polymer from the TSV tips prior to the CMP step sufficient to expose the inner metal core.

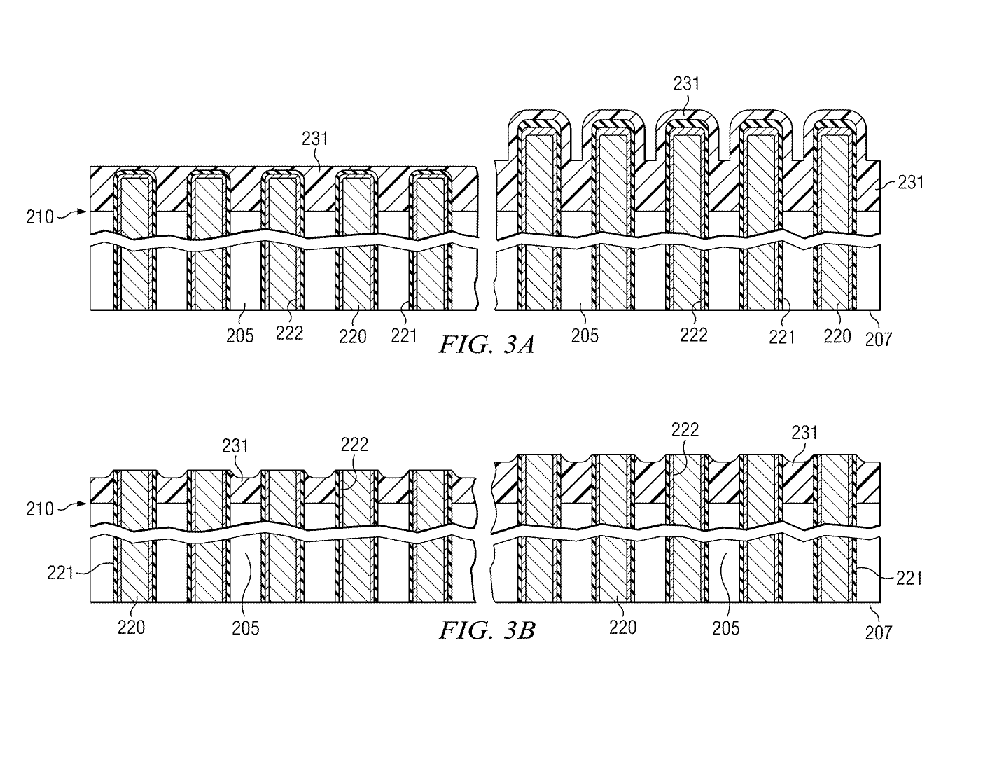

In a second embodiment (see FIGS. 3A-B described below) the CMP process includes a first CMP step including a first CMP slurry that provides a first removal rate ratio (selectivity) for removing the dielectric liner and inner metal core relative to removing the polymer or polymer precursor, and a second CMP step including a second CMP slurry that provides a second removal rate ratio (selectivity) for removing the dielectric liner and the inner metal core relative to removing the polymer or polymer precursor. The first removal rate ratio is less than the second removal rate ratio. The first CMP step thus provides a relatively smaller TSV/polymer removal rate ratio; while the second CMP step provides a relatively higher TSV/polymer removal ratio. The second embodiment avoids the need for the ex-situ polymer wet strip process disclosed for the first embodiment, but involves an additional CMP step to remove the polymer from the top of the TSV tips.

Step 103 comprises the optional step of forming a metal cap on the TSV tips comprising at least one metal layer that includes a metal that is not in the inner metal core. The metal layer for the metal cap is exclusive of solder can be electrolessly or electrolytically deposited (i.e., electroplating) on a distal portion of the protruding TSV tips. The first metal layer forms an electrical contact with at least the topmost surface of the inner metal core of the TSV tip.

The first metal layer can be generally 1 μm to 8 μm thick. The first metal layer can provide an intermetallic compound (IMC) block. The first metal layer can comprise materials including Ni, Pd, Ti, Au, Co, Cr, Rh, NiP, NiB, CoWP or CoP, for example. In one specific embodiment, the first metal layer can comprise a 3 μm to 8 μm thick electroplated Cu layer. In one embodiment the inner metal core comprises copper and the TSV tips include a metal cap that includes at least one of Ti, Ni, Pd, and Au.

The metal caps can include a second metal layer exclusive of solder that is different from the first metal layer on the first metal layer. The combined thickness of the first and second metal layers can be 1 μm to 10 μm. One metal cap arrangement comprises Ni/Au.

FIGS. 2A-E show successive cross sectional depictions corresponding to steps in an example method of fabricating TSV die that is based on the first embodiment of method 100 described above, according to an example embodiment. The left and right sides of the respective FIGs. are intended to show within-a-wafer process variation. FIG. 2A shows the substrate (e.g., wafer) 205 having a plurality of embedded TSVs 276 having a topside 207 and bottomside 210 after bottomside wafer thinning, such as using a carrier wafer-based thinning process, for example to a thickness of 60 μm to 80 μm from an initial (pre-thinning) thickness of about 500 μm to 750 μm. The distance between the distal end of the embedded TSVs 276 and the bottomside 210 are shown having a range across the substrate 205, such as a ±2.5 μm variation indicated by a maximum distance 281 and a minimum distance 282 as shown in FIG. 2A.

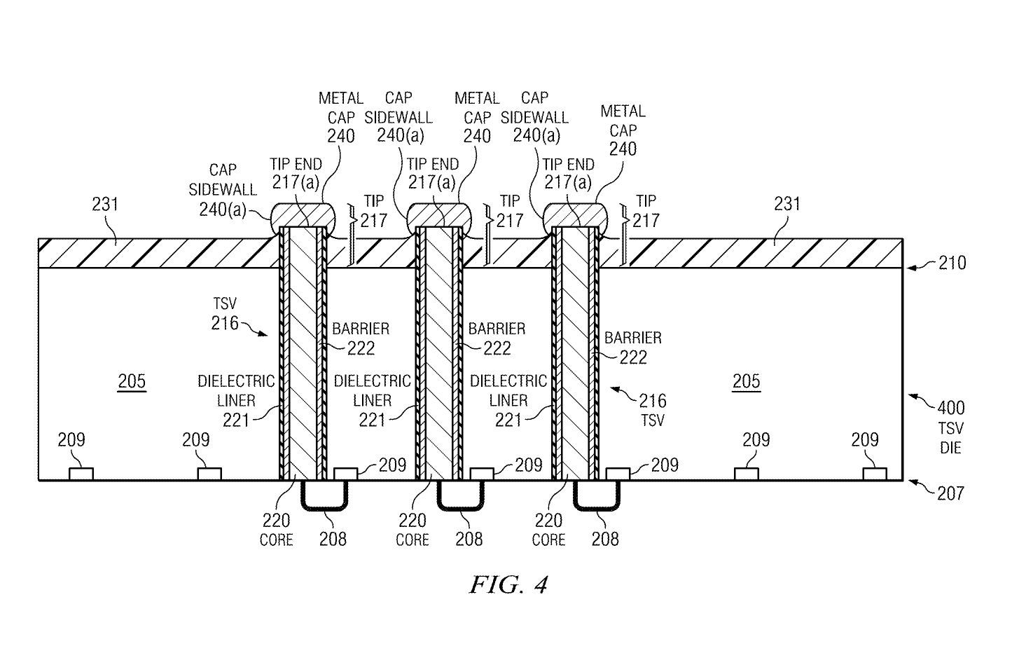

The topside 207 includes active circuitry (see active circuitry 209 shown in FIG. 4). The embedded TSVs 276 are shown including a liner comprising a dielectric liner (or dielectric sleeve) 221 and diffusion barrier layer 222 with an inner metal core 220 within the diffusion barrier layer 222. The TSVs are generally coupled to the contact level or one of the back end of the line (BEOL) metal layers (e.g., M1, M2, etc.) on the topside 207. In one embodiment the TSV diameter is ≦12 μm, such as 4 μm to 10 μm in one particular embodiment.

The inner metal core 220 can comprise copper in one embodiment. Other electrically conductive materials can be used for the inner metal core 220. The dielectric liner can comprise materials such as silicon oxide, silicon nitride, phosphorus-doped silicate glass (PSG), silicon oxynitride, or certain chemical vapor deposited (CVD) polymers (e.g., parylene). The dielectric liner is typically 0.2 to 5 μm thick.

In the case of copper and certain other metals for the inner metal core 220, a diffusion barrier layer 222, such as a refractory metal or a refractory metal nitride, is generally added and is deposited on the dielectric liner 221. For example, diffusion barrier layers can include materials including Ta, W, Mo, Ti, TiW, TiN, TaN, WN, TiSiN or TaSiN, which can be deposited by physical vapor deposition (PVD) or CVD. The diffusion barrier layer 222 is typically 100 Å to 500 Å thick.

FIG. 2B shows the substrate (wafer) 205 after substrate (e.g., silicon) etch to form TSV tips 217 that protrude from the bottomside 210 of the substrate 205. In one embodiment a median length of the protruding TSV tips 217 measured from the bottomside 210 of the substrate is from 2 μm to 15 μm. The TSV tips 217 are shown having a range of lengths across the substrate (e.g., wafer) 205, such as a ±2.5 μm variation.

FIG. 2C shows the substrate (wafer) 205 after coating a layer 231 of polymer or polymer precursor, corresponding to step 101 in method 100. In one embodiment a spin-on process is used. The layer 231 coating can be seen to form a planar (flat) top. For improved thickness uniformity, the thickness of layer 231 is selected to cover the tallest of the TSV tips 217, such as a coating thickness of 8 μm to 10 μm when the length of the tallest TSV tips are about 7 μm.

FIG. 2D shows the substrate (wafer) 205 after developing (a purely solution-based removal process) to remove a portion of the layer 231 of polymer or polymer precursor. The develop process is selected to retain some of the layer 231 of polymer over the field region on the bottomside 210 that is between the TSV tips 217. In one specific embodiment, the develop process removes about 6 μm of the layer 231 of polymer or polymer precursor. A cure (crosslinking) process for cross linkable polymers can follow the develop step.

FIG. 2E shows the substrate (wafer) 205 after CMP processing that provides a substantially higher removal rate for removal of the dielectric liner 221, diffusion barrier layer 222 and generally the inner metal core 220, relative to the removal rate for the layer 231 of polymer or polymer precursor, corresponding to step 102 in method 100. This CMP process removes the liner 221/222 over a top of the TSV tips 217 to reveal the metal core 220. The selectivity of the CMP process is selected so as to reduce the variation in length of TSV tips 217 as shown in FIG. 2E, such as to <±1 μm, and to preserve some of the layer 231 of polymer over the field region between the TSV tips 217.

The thickness of the layer 231 of polymer over the field region can be 1 μm to 3 μm. Accordingly, any metal from exposure of the inner metal core 220 that deposits in the field region between the TSV tips is on the layer 231 of polymer over the field region, and not directly on the substrate 205. As described above, layer 231 of polymer has been found to effectively block diffusion of the inner metal core 220, and thus prevents the metal from inner metal core 220 from reaching the substrate (e.g., silicon).

FIGS. 3A-B show successive cross sectional depictions corresponding to steps in an example method of fabricating TSV die that is based on the second embodiment of method 100 described above, according to an example embodiment. The second embodiment includes processing corresponding to FIGS. 2A-B.

FIG. 3A shows the substrate (wafer) 205 after coating of a layer 231 of polymer or polymer precursor, corresponding to step 101 in method 100. Unlike the first embodiment described relative to FIGS. 2A-E, the layer of polymer 231 is intentionally not thick enough to form a planar top surface over the tallest TSV tips. The layer of polymer 231 is coated to a thickness approximately equal to the protrusion amount of the shortest TSV tips. In the case of a curable polymer, curing can follow coating. In one embodiment the thickness of the layer 231 of polymer is 3 μm to 5 μm.

The TSV inner metal core revelation process for the second embodiment can comprise a 2-step CMP. The first CMP step can comprise CMP using a slurry that provides a first removal rate ratio (selectivity) for removing the dielectric liner and inner metal core slower relative to removing the polymer or polymer precursor. The first CMP step removes polymer from the TSV tip region. The second CMP step can use a CMP process including a second CMP slurry that provides a second removal rate ratio (selectivity) for removing the dielectric liner and the inner metal core substantially faster relative to removing the polymer or polymer precursor. The first removal rate ratio is substantially less than the second removal rate ratio. The second CMP step can remove some polymer or polymer precursor, but typically at least 1 μm to 3 μm of polymer remains on the bottomside 210 after CMP.

As noted above, for the first embodiment the variation in lengths of TSV tips 217 across the wafer following revelation of the TSV tips as shown in FIG. 2E is generally <±1 μm. In contrast, for the second embodiment the variation in lengths of TSV tips 217 across the wafer following revelation of the TSV tips shown in FIG. 3B will generally be somewhat more, such as <±2 μm.

Advantages of disclosed embodiments include a significant cost and cycle time benefit as compared to known TSV tip reveal processes. Use of spin-on polymer and optional develop-back is significantly less expensive than chemical vapor deposition (CVD) for oxide/nitride, and is also a faster process. Polymer spin coat, develop, and cure (if applicable) are generally readily available in factories that perform bump assembly. The forming temperature for the polymer can also be reduced as compared to CVD-based inorganic dielectrics, such as from at least 220° C. for CVD to 190° C. or less, which can improve the margin for temporary adhesives that may be used. Another advantage over inorganic bottomside dielectric passivation is having both die bonding surfaces coated with same/similar polymer passivation material that is favorable for underfills which then can be engineered for adhesion to the polymeric material. Polymer materials also generally provide a better stress buffer as compared to inorganic dielectrics (e.g., silicon oxide or silicon nitride) between bonded die.

FIG. 4 is a simplified cross sectional depiction of an example through substrate via (TSV) die 400 having TSVs 216 including protruding TSV tips 217 from bottomside 210 of the substrate 205 and a polymer layer 231 in the field region between the TSV tips having metal caps 240 thereon, according to an example embodiment. Although the metal cap 240 is shown as an electroless metal cap, the metal cap may also be electroplated.

The polymer layer 231 can be seen to be substantially flush with respect to the top of the inner metal core 220 at the TSV distal tip end 217(a). As used herein, “substantially flush” refers to a thickness of the polymer 231 adjacent to the TSV 216 approximately equal to a length from the bottomside 210 to the distal tip end 217(a). The thickness of the polymer 231 is shown gradually approaching a lower nominal field thickness at increasing distances from the TSV 216. As used herein, “approximately equal to a length from the bottomside 210 to the distal tip end 217(a)” refers to being within 2 μm in thickness, such as being within 1 μm in thickness in one embodiment. TSV die 400 corresponds to the TSV die resulting from practice of the methods described above, including an optional metal cap formation process. The protruding TSV tips 217 are shown having the optional metal cap 240 on their distal tip ends 217(a). The sidewall of the metal cap 240 is shown as 240(a).

TSV die 400 comprises a substrate 205 including a topside 207 including active circuitry 209 and a bottomside 210. The active circuitry 209 on TSV die 400 is configured to provide an IC circuit function, such as a logic function, for example. The connectors 208 shown depict the coupling between the TSVs 216 on the topside 207 to the active circuitry 209. The connection to active circuitry 209 is optional, since the connection may simply pass through substrate 205 without connecting to active circuitry 209, such as for a power supply connection.

The TSVs 216 comprise a dielectric sleeve 221 and an inner metal core 220, and a diffusion barrier layer 222 between the outer dielectric sleeve 221 and the inner metal core 220. The TSVs 216 extends from the topside 207 to protruding TSV tip 217 emerging from the bottomside 210 of substrate 205. The TSV tips 217 include sidewalls having outer dielectric sleeve 221 and diffusion barrier layer 222 thereon.

For example, in one particular embodiment the TSV tip ends 217(a) extend out about 5 μm from the bottomside 210 of TSV die 400, the metal caps 240 add about 5 μm in height to the TSV tips 217, and the polymer layer 231 thickness is in the range from 1 to 4 μm thick. The active circuitry formed on the substrate having a semiconductor surface comprises circuit elements that may generally include transistors, diodes, capacitors, and resistors, as well as signal lines and other electrical conductors that interconnect the various circuit elements to provide an IC circuit function. As used herein “provide an IC circuit function” refers to circuit functions from ICs, that for example may include an application specific integrated circuit (ASIC), a digital signal processor, a radio frequency chip, a memory, a microcontroller and a system-on-a-chip or a combination thereof.

Disclosed embodiments can be integrated into a variety of process flows to form a variety of devices and related products. The semiconductor substrates may include various elements therein and/or layers thereon. These can include barrier layers, other dielectric layers, device structures, active elements and passive elements, including source regions, drain regions, bit lines, bases, emitters, collectors, conductive lines, conductive vias, etc. Moreover, disclosed embodiments can be used in a variety of semiconductor device fabrication processes including bipolar, CMOS, BiCMOS and MEMS processes.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method of forming semiconductor die, comprising:
forming a layer of polymer or a precursor of said polymer on a bottomside of a substrate having a topside including active circuitry, and a plurality of through substrate vias (TSVs), said TSVs having a liner comprising at least a dielectric liner and an inner metal core that extends to TSV tips that protrude from said bottomside, wherein said layer of said polymer or said precursor and said liner cover said plurality of TSV tips and said layer of said polymer or said precursor is between said plurality of TSV tips on said bottomside, and
removing said polymer or said precursor and said liner over a top of said TSV tips to reveal said metal core, wherein after said removing said polymer or said precursor remains on said bottomside between said TSV tips.

2. The method of claim 1, wherein said removing comprises chemical mechanical polishing (CMP) said bottomside of said substrate.

3. The method of claim 2, wherein said forming comprises forming a planar layer of said polymer or said precursor, and said CMP comprises using a CMP process including a CMP slurry that provides a faster removal rate for said liner and said inner metal core as compared to a removal rate for said polymer or said precursor of said polymer.

4. The method of claim 2, wherein said CMP comprises:
a first CMP step using a CMP process including a first CMP slurry that provides a first removal rate ratio for removing said liner and said inner metal core relative to removing said polymer or said precursor of said polymer, and
a second CMP step using a CMP process including a second CMP slurry that provides a second removal rate ratio for removing said liner and said inner metal core relative to removing said polymer or said precursor of said polymer,
wherein said first removal rate ratio is less than said second removal rate ratio.

5. The method of claim 1, wherein said polymer comprises benzocyclobutene (BCB), polybenzoxazole (PBO), parylene, or a polyimide (PI).

6. The method of claim 1, wherein said liner further comprises a diffusion barrier layer between said dielectric liner and said inner metal core.

7. The method of claim 1, wherein said inner metal core comprises copper.

8. The method of claim 2, further comprising curing said precursor after said CMP.

9. The method of claim 1, wherein said forming comprises a spin-on process.

10. The method of claim 1, wherein said substrate comprises silicon and said plurality of TSVs comprise through-silicon-vias.

11. A through-substrate-via (TSV) die, comprising:
a substrate having a topside including active circuitry and bonding features on said topside, a bottomside, and a plurality of TSVs having a liner comprising at least a dielectric liner and an inner metal core that extends to TSV tips that protrude outward from said bottomside, and
a polymer on said bottomside of said substrate between said TSV tips, but not over a inner metal core top of said TSV tips to reveal said metal core, wherein said polymer is substantially flush with respect to said inner metal core top of said TSV tips.

12. The TSV die of claim 11, wherein said TSV tips include a metal cap thereon comprising at least one metal layer that includes a metal that is not in said inner metal core.

13. The TSV die of claim 12, wherein said inner metal core comprises copper and wherein said metal cap thereon that includes at least one of titanium, nickel, palladium, and gold.

14. The TSV die of claim 11, wherein said polymer comprises benzocyclobutene (BCB), polybenzoxazole (PBO), parylene, or a polyimide (PI).

15. The TSV die of claim 11, wherein said liner further comprises a diffusion barrier layer between said dielectric liner and said inner metal core.

16. The TSV die of claim 11, wherein said substrate comprises silicon and said plurality of TSVs comprise through-silicon-vias.
